(19) United States
(12) Patent Application Publication
(10) Pub. No.: US 2026/0068289 A1
(43) Pub. Date: Mar. 5, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Keiko KAWAMURA, Yokohama Kanagawa (JP); Yoko IWAKAJI, Meguro Tokyo (JP); Shinya SATO, Nonoichi Ishikawa (JP)

(21) Appl. No.: 19/310,844

(22) Filed: Aug. 26, 2025

(30) Foreign Application Priority Data
Sep. 5, 2024 (JP) 2024-153441
Feb. 26, 2025 (JP) 2025-028600

(51) Int. Cl. H10D 84/00; H10D 84/01

(52) U.S. Cl. CPC H10D 84/146; H10D 84/0109

(57) ABSTRACT

According to one embodiment, a semiconductor device includes a first semiconductor region of a first conductive type between a first electrode and a second electrode. A third electrode extends from the first electrode toward the second electrode. A fourth electrode faces the third electrode. A second semiconductor region of second conductive type which is between the third electrode and the fourth electrode and contacts the third electrode. An insulation layer is in contact with the fourth electrode and faces the third electrode. A third semiconductor region of first conductive type is between the second electrode and the second semiconductor region. The third semiconductor region has a higher impurity concentration than the first semiconductor region.

### CROSS-REFERENCE TO RELATED APPLICATION(S)

This application is based upon and claims the benefit of priority from Japanese Patent Application No. 2024-153441, filed Sep. 5, 2024, and Japanese Patent Application No. 2025-028600, filed Feb. 26, 2025, the entire contents each of which are incorporated herein by reference.

### FIELD

Embodiments described herein relate generally to a semiconductor device.

### BACKGROUND

Semiconductor devices such as a metal oxide semiconductor field effect transistor (MOSFET) and an insulated gate bipolar transistor (IGBT) are used as power semiconductor devices to control high voltages and high currents. These power semiconductor devices are required to perform highly efficient power control with low on-resistance.

### BRIEF DESCRIPTION OF THE DRAWINGS

FIG. 1 is a schematic cross-sectional view illustrating a semiconductor device according to a first embodiment.

FIG. 2 is a cross-sectional view illustrating a broken line A portion in FIG. 1.

FIG. 3 is a schematic cross-sectional view illustrating a semiconductor device according to a comparative example.

FIG. 4 is a cross-sectional view of a semiconductor device according to a first modification example.

FIG. 5 is a cross-sectional view of a semiconductor device according to a second modification example.

FIG. 6 is a cross-sectional view of a semiconductor device according to a third modification example.

FIG. 7 is a cross-sectional view of a semiconductor device according to a fourth modification example.

FIG. 8 is a cross-sectional view of a semiconductor device according to a fifth modification example.

FIG. 9 is a cross-sectional view of a semiconductor device according to a sixth modification example.

FIG. 10 is a cross-sectional view of a semiconductor device according to a sixth modification example.

FIGS. 11A to 11E are schematic cross-sectional views depicting aspects of a first manufacturing process related to a third electrode.

FIGS. 12A to 12D are schematic cross-sectional views depicting aspects of a second manufacturing process related to a third electrode.

FIGS. 13A to 13C are schematic cross-sectional views depicting aspects of a third manufacturing process related to a third electrode.

FIGS. 14A to 14E are schematic cross-sectional views depicting aspects of a fourth manufacturing process related to a third electrode.

### DETAILED DESCRIPTION

Embodiments provide a semiconductor device that can perform highly efficient power control while having a low on-resistance.

In general, according to one embodiment, a semiconductor device includes a first electrode; a second electrode separated from the first electrode in a first direction; a first semiconductor region of a first conductivity type between the first electrode and the second electrode; a third electrode extending from the second electrode toward the first electrode in the first direction, the third electrode being on an upper side of the first semiconductor region; a fourth electrode separated from the third electrode in a second direction orthogonal to the first direction; a second semiconductor region of a second conductivity type between the third electrode and the fourth electrode in the second direction, the second semiconductor region contacting the third electrode; an insulation layer including a first insulation region contacting the fourth electrode, the first insulation region being between the third electrode and the fourth electrode in the second direction; and a third semiconductor region of a first conductivity type between the second electrode and the second semiconductor region in the first direction, the third semiconductor region having a higher impurity concentration than the first semiconductor region.

Certain example embodiments will be described below with reference to the accompanying drawings. In this description, parts or aspects depicted in more than drawing are denoted by the same reference symbols throughout each of the drawings. It should be noted that these examples are not intended to limit the present disclosure. Similarly, the depicted dimensions, dimensional ratios, and the like in the drawings are not limitations on the dimensions, sizing ratios, and the like unless stated as such. In the following description, generally, a first conductivity type is described as an n-type and a second conductivity type as a p-type, but this does not limit the disclosure. In other examples, first conductivity type may be a p-type and the second conductivity type may be an n-type.

### First Embodiment

### Configuration of Semiconductor Device 100

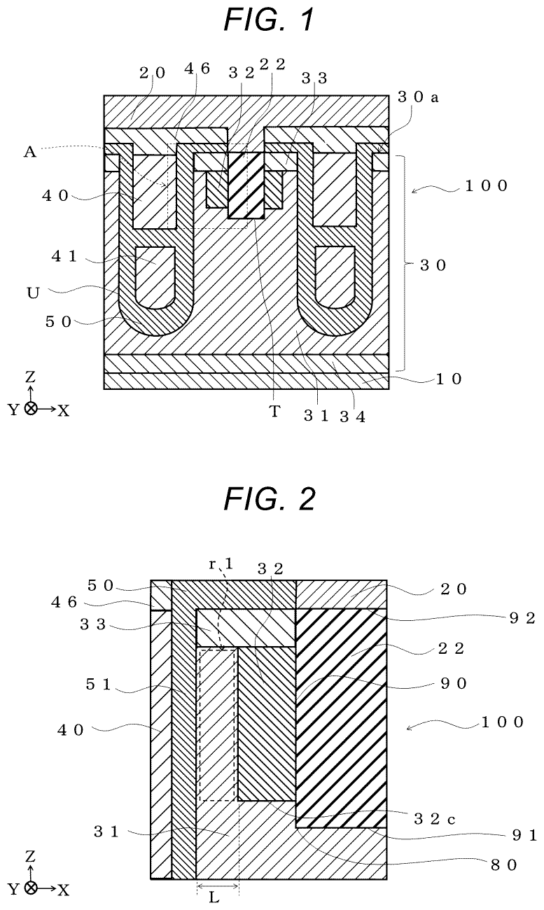

The configuration of a semiconductor device 100 according to a first embodiment will be described with reference to FIG. 1 and FIG. 2. The semiconductor device 100 illustrated in FIG. 1 is, for example, a metal oxide silicon field effect transistor (MOSFET). As illustrated in FIG. 1, the semiconductor device 100 includes a first electrode 10, a second electrode 20, a semiconductor portion 30, a third electrode 22, a fourth electrode 40, an insulation layer 50, and an interlayer insulation layer 46. In the present embodiment, a configuration in which a fifth electrode 41 is further included is described, but this does not limit the disclosure.

A direction from the first electrode 10 toward the second electrode 20 is defined as a first direction and corresponds to a Z direction. One direction perpendicular to the Z direction is defined as a second direction and corresponds to an X direction. A direction perpendicular to the Z direction and the X direction is defined as a third direction and corresponds to a Y direction. For convenience of description, the first direction is an upward direction and a direction opposite to the first direction is a downward direction.

A direction from the first electrode 10 to the semiconductor portion 30 extends along the Z direction. The semiconductor portion 30 includes a first semiconductor region 31, a second semiconductor region 32, a third semiconductor region 33, and a fourth semiconductor region 34. In the semiconductor portion the first semiconductor region 31, the third semiconductor region 33, and the fourth semiconductor region 34 are of the first conductivity type (e.g., the n-type). The second semiconductor region 32 is of the second conductivity type (e.g., the p-type).

The first semiconductor region 31 is provided between the first electrode 10 and the second electrode 20. A direction from the first semiconductor region 31 to the second electrode 20 extends along the Z direction. The second semiconductor region 32 is provided on the upper side of the first semiconductor region 31 and is in contact with the third electrode 22 in the X direction.

The third semiconductor region 33 is provided between the second electrode 20 and the first semiconductor region 31 and is in contact with the third electrode 22 in the X direction. The fourth semiconductor region 34 is provided between the first electrode 10 and the first semiconductor region 31 and is in contact with the first semiconductor region 31 on the XY plane.

The third semiconductor region 33 contains a larger amount of n-type impurities than the first semiconductor region 31. The fourth semiconductor region 34 contains a larger amount of n-type impurities than the first semiconductor region 31. When the concentration of impurities of the first conductivity type in the first semiconductor region 31 is, for example, between 1×10¹⁵ atoms/cm³ and 2×10¹⁷ atoms/cm³, the concentration of impurities of the first conductivity type in the third semiconductor region 33 and the fourth semiconductor region 34 is, for example, between 1×10¹⁷ atoms/cm³ and 1×10²¹ atoms/cm³. It should be noted that the fourth semiconductor region 34 is provided between the first electrode 10 and the second electrode 20 so as to reduce an electric resistance, but is not an essential component of all examples.

A trench U is provided from an upper surface 30a of the semiconductor portion 30 toward a direction opposite to the positive direction of the Z direction. The trench U extends continuously in the Y direction, for example. A plurality of trenches U may be provided at intervals in the X direction.

The insulation layer 50 is provided in the trench U. The fourth electrode 40 and the fifth electrode 41 are enclosed by the insulation layer 50 in the trench U. The insulation layer 50 is in contact with the fourth electrode 40, the fifth electrode 41, and the first semiconductor region 31. The insulation layer 50 electrically insulates between the fourth electrode 40 and the first semiconductor region 31, between the fifth electrode 41 and the first semiconductor region 31, and between the fourth electrode 40 and the fifth electrode 41. The interlayer insulation layer 46 electrically insulates between the fourth electrode 40 and the second electrode 20.

A trench T is provided from the upper surface 30a toward a direction opposite to the positive direction of the Z direction between arbitrary trenches U out of a plurality of trenches U provided in the X direction.

The third electrode 22 is provided in the trench T. The third electrode 22 is a trench contact electrically connected to the second electrode 20. According to FIG. 2, the third electrode 22 is surrounded by a wall surface 90 that extends along the Z direction, a bottom surface 91 that extends along the X direction and faces the first semiconductor region 31, and a top surface 92 that extends along the X direction and faces the second electrode 20. The third electrode 22 has a corner portion 80 where the wall surface 90 and the bottom surface 91 intersect. The corner portion 80 can be an acute angle, an obtuse angle, a right angle, or chamfered. The shape of the corner portion 80 is determined by design and aspects of the manufacturing process. Additionally, if the bottom surface 91 is curved but continuously connected to the wall surface 90, the portion where the curvature of the bottom surface 91 changes can be considered the corner portion 80. The wall surface 90, bottom surface 91, and top surface 92 can be considered as included in the third electrode 22.

FIG. 2 illustrates a broken line A portion enclosed by a broken line in FIG. 1. According to FIG. 2, the insulation layer 50 includes a first insulation region 51 between the first semiconductor region 31 and the fourth electrode 40 in the X direction. The second semiconductor region 32 need not be in contact with the third semiconductor region 33 in the Z direction in all examples. The second semiconductor region 32 is provided between the first semiconductor region 31 and the third electrode 22 in the X direction. A first channel region r1 is formed between the second semiconductor region 32 and the first insulation region 51. The first channel region r1 will be described below along the description of an operation of the semiconductor device 1.

The fourth electrode 40 and the fifth electrode 41 illustrated in FIG. 1 may contain, for example, at least one of polysilicon or metal. The second electrode 20 contains, for example, at least one selected from the group including Al, Cu, Mo, W, Ta, Co, Ru, Ti, and Pt. The first electrode 10 contains, for example, at least one selected from the group including Al, Cu, Mo, W, Ta, Co, Ru, Ti, Ni, and Pt. When the first conductivity type is an n-type as in the present embodiment, the metal of the third electrode 22 is preferably selected from metals having a work function allowing a Schottky junction with the first semiconductor region 31. For example, the metals having a work function of 4.3 eV or higher include at least one selected from the group including Ir, Pd, Au, Ti, Cr, Fe, Cu, Zr, Mo, Ru, Ag, Pt, Nd, Bi, Ni, Co, and the like.

The fifth electrode 41 illustrated in FIG. 1 may be electrically connected to the second electrode 20 through a wiring and the like. For example, the fifth electrode 41 functions as a field plate. In this case, when the MOSFET performs an off-operation (turn off), a depletion layer can be expanded in the first semiconductor region 31 and the withstand voltage can be maintained.

### Operation of Semiconductor Device 100

An operation of the semiconductor device 100 will be described. For example, when the semiconductor device 100 is a MOSFET, the current flowing between the first electrode 10 and the second electrode 20 can be controlled by controlling the potential of the fourth electrode 40. The first electrode 10 functions as a drain electrode, for example. The second electrode 20 functions as a source electrode, for example. The third electrode 22 has the same potential as the second electrode 20 and is a source electrode. The third semiconductor region 33 functions as a source region, for example. The first channel region r1 indicated by a broken line in FIG. 2 includes a depletion layer due to a pn junction between the second semiconductor region 32 and the first semiconductor region 31, and functions as a channel region, for example. The fourth electrode 40 functions as a gate electrode, for example. The first insulation region 51 functions as a gate insulation film, for example. A depletion layer is formed due to a Schottky junction at an interface at which the third electrode 22 and the first semiconductor region 31 are in contact with each other.

The first channel region r1 is opposed to and in contact with the second semiconductor region 32 and the first insulation region 51 in the X direction. The first channel region r1 is also opposed to and in contact with the third semiconductor region 33 provided at a surface of the first semiconductor region 31 in the Z direction. The first channel region r1 is region in which the carrier density varies depending on the potential of the fourth electrode 40. The first channel region r1 is not necessarily limited to the area surrounded by the dashed lines depicted in the figures.

The thickness (a distance in the X direction) of a depletion layer due to a pn junction formed at the interface between the first channel region r1 and the second semiconductor region 32 illustrated in FIG. 2 is controlled by the potential of the fourth electrode 40. That is, a carrier density in the first channel region r1 is controlled by the fourth electrode 40. When the carrier density is low, substantially no current flows between the third electrode 22 and the first electrode 10 and between the second electrode 20 and the first electrode 10. That is, an off-state is obtained. When the carrier density in the first channel region r1 is increased by controlling the potential of the fourth electrode 40, a current flows between the third electrode 22 and the first electrode 10 and between the second electrode 20 and the first electrode 10. That is, an on-state is obtained.

As described above, the semiconductor device 100 has a depletion layer that is formed by the first channel region r1 between the second semiconductor region 32 (which is in contact with the third electrode 22 in the X direction) and the first insulation region 51. The carrier density of the depletion layer formed in the first channel region r1 can be controlled by the fourth electrode 40.

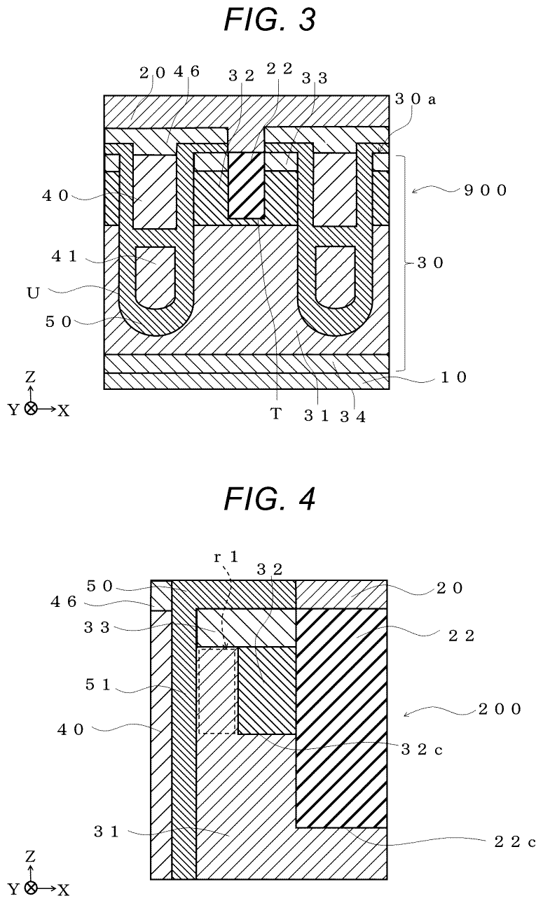

Here, a semiconductor device 900 of a comparative example is illustrated in FIG. 3. In the semiconductor device 900, the second semiconductor region 32 of the second conductivity type provided between the second electrode 20 and the first electrode 10 is in contact with both the third electrode 22 and the first insulation region 51 in the X direction. The second semiconductor region 32 has a thickness in the Z direction.

In the semiconductor device 900, a depletion layer is formed at the interface where the second semiconductor region 32 and the first semiconductor region 31 are in contact with each other in the Z direction. The electrical connection between the first electrode 10 and the second electrode 20 is blocked by the depletion layer formed on an X-Y plane in the second semiconductor region 32. When a voltage is applied to the fourth electrode 40, carriers gather at the interface at which the second semiconductor region 32 and the insulation layer 50 are in contact with each other to form a channel, whereby the on-state is obtained.

In contrast, in the semiconductor device 100, a depletion layer is formed at the interface where the second semiconductor region 32 and the first semiconductor region 31 are in contact with each other in the X direction. That is, the semiconductor device 100 does not need to be provided with a second semiconductor region 32 that is in contact with both the third electrode 22 and the first insulation region 51 in as in the semiconductor device 900. Accordingly, the semiconductor device 100 can provide a semiconductor device that can reduce an on-resistance.

### First Modification Example

FIG. 4 is a schematic diagram of a semiconductor device 200 according to a first modification example of the first embodiment.

The semiconductor device 200 is an example in which a lowermost point 32c of the second semiconductor region 32 is located closer to the second electrode 20 in the Z direction than is a lowermost point 22c of the third electrode 22. Additionally, the lowermost point 22c is considered included in or as a part of the bottom surface 91. In such ana semiconductor device 200, an on-resistance and a reverse recovery charge amount Qrr can be reduced as compared with the semiconductor device 100. Reduction in Qrr can shorten a recovery time at turn-off. It should be noted that the lowermost point 32c is illustrated as having a planar (flat) shape in FIG. 4, but is not limited thereto. From a concentration distribution in consideration of a diffusion width of the second semiconductor region 32, some point along the Z axis can be determined as the lowermost point.

### Second Modification Example

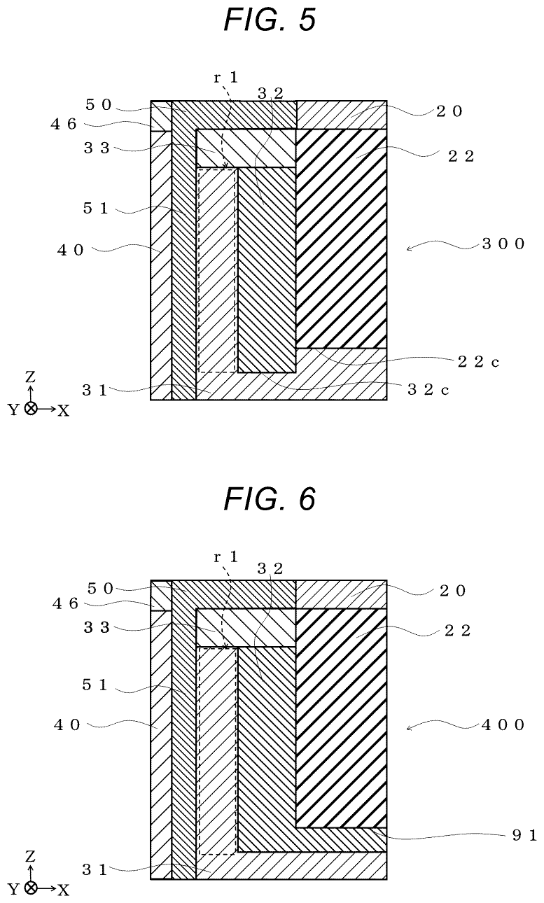

FIG. 5 is a schematic diagram of a semiconductor device 300 according to a second modification example of the first embodiment.

The semiconductor device 300 is an example in which the lowermost point 32c of the second semiconductor region 32 is located closer to the first electrode 10 in the Z direction than is the lowermost point 22c of the third electrode 22. Accordingly, the dimension in the Z direction of the depletion layer formed in the first channel region r1 is increased. Therefore, the distance (length) of the first channel region r1 in the Z direction increases, and the withstand voltage of the entire device increases. That is, a leakage current between source and drain via the first channel region r1 can be reduced.

### Third Modification Example

FIG. 6 is a schematic diagram of a semiconductor device 400 according to a third modification example of the first embodiment.

In the semiconductor device 400, the second semiconductor region 32 is formed over the entire interface between the third electrode 22 and the first semiconductor region 31. The second semiconductor region 32 surrounds an outer surface of the third electrode 22. The outer surface here is a continuous surface on which the third electrode is in contact with the second semiconductor region 32. Accordingly, a depletion layer due to a pn junction is formed to cover the outer surface of the third electrode 22. Since the depletion layer is also formed from the bottom portion of the third electrode 22, the distance of the depletion layer blocking between the source and the drain is increased, and the leakage current can be reduced.

### Fourth Modification Example

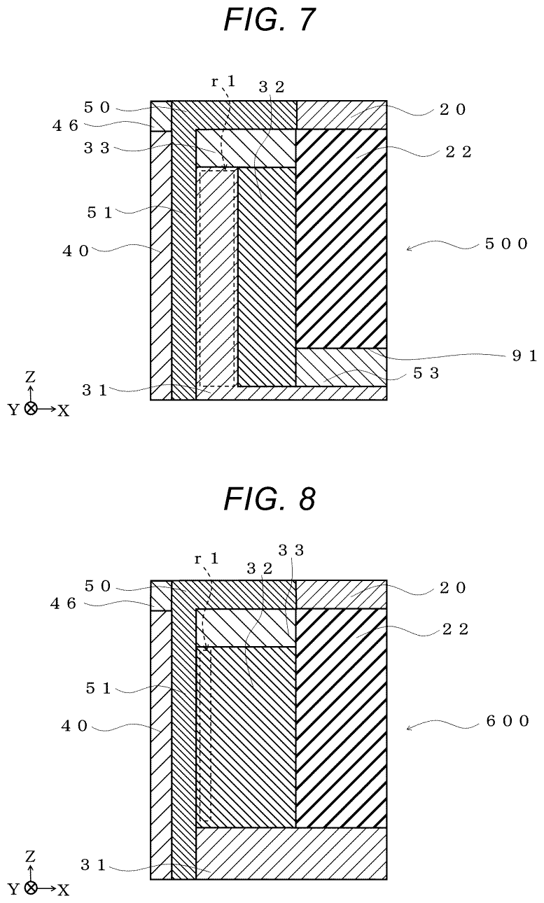

FIG. 7 is a schematic diagram of a semiconductor device 500 according to a fourth modification example of the first embodiment.

In the semiconductor device 500, an insulation layer 53 is further provided on the bottom surface 91 of the third electrode 22 in the configuration of the semiconductor device 300. This brings an advantage of reducing the leakage current from the bottom surface 91 of the third electrode 22 as in the semiconductor device 400.

### Fifth Modification Example

FIG. 8 is a schematic diagram of a semiconductor device 600 according to a fifth modification example of the first embodiment.

In the semiconductor device 600, the second semiconductor region 32 is provided between the first insulation region 51 and the third electrode 22 and is furthermore in contact with both the first insulation region 51 and the third electrode 22 in the X direction. In addition, the second semiconductor region 32 has a concentration gradient of the second conductivity type impurities in the X direction, and the concentration of the second conductivity type generally decreases from the third electrode 22 toward the first insulation region 51. For example, the concentration distribution has a slope close to that of a Gaussian distribution in accordance with a diffusion equation.

In a portion of the second semiconductor region 32 in which the concentration of the second conductivity type is low, an accumulation layer is easily formed when a gate voltage is applied, and a channel resistance can be reduced. On the other hand, when the gate voltage is set to be 0 V or less, the channel portion is blocked, and the off-state can be kept. In such a semiconductor device 600, since the second semiconductor region 32 covers up to the first channel region r1, the second semiconductor region 32 is formed between the source and the drain, and the leakage current between the source and the drain can be reduced, as compared with the semiconductor device 100 according to the first embodiment. It should be noted that the concentration of the second conductivity type of the second semiconductor region 32 may reach zero or substantially so at the part in contact with the first insulation region 51.

### Sixth Modification Example

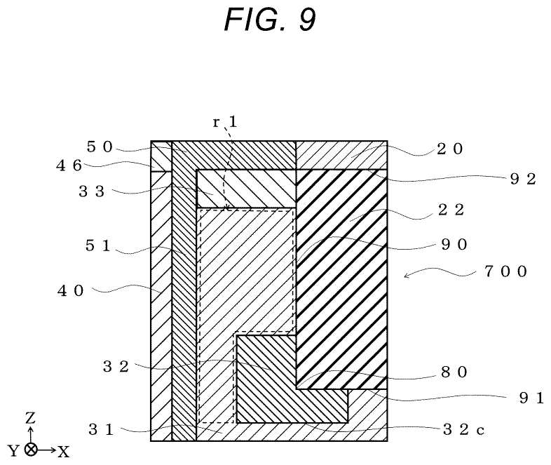

FIG. 9 is a partial schematic diagram of a semiconductor device 700 according to a sixth modification of the first embodiment.

The semiconductor device 700 is configured such that the second semiconductor region 32 surrounds the corner portion 80 of the third electrode 22. In other words, as shown in FIG. 9, at least a part of the third electrode 22 is in contact with the second semiconductor region 32 in the X direction. The third electrode 22 is also in contact with both the first semiconductor region 31 and the second semiconductor region 32 in the Z direction. Additionally, the wall surface 90 of the third electrode 22 may be in contact with the first semiconductor region 31 in the X direction.

In such a semiconductor device 700, a first channel region r1 is formed between the third electrode 22 and the first insulation region 51. The semiconductor device 700 has a depletion layer spreading from the interface of the first semiconductor region 31 to surround the second semiconductor region 32, thereby blocking the first channel region r1 between the first insulation region 51 and the second semiconductor region 32. This allows the leakage current from the third electrode 22 to the first channel region r1 to be blocked. The depletion layer that extends to surround the second semiconductor region 32 can also block leakage current from the third electrode toward the first electrode 10. Additionally, the device semiconductor 700, like the semiconductor devices 300 to 600, can reduce channel resistance by omitting the P-base layer in the channel region, which consequently enables a lower on-resistance.

In the semiconductor device 700, by not completely covering the third electrode 22 with the second semiconductor region 32, a region where part of the bottom surface 91 of the third electrode 22 is in contact with the first semiconductor region 31 is formed. As a result, a Schottky junction is formed at the interface between the third electrode 22 and the first semiconductor region 31. Consequently, compared to a structure consisting solely of a PN junction, this configuration enables a lower forward voltage and a shorter reverse recovery time.

### Seventh Modification Example

FIG. 10 is a partial schematic diagram of a semiconductor device 800 according to a seventh modification of the first embodiment.

The semiconductor device 800 has a shape where the width (in the X direction) of the third electrode 22 gradually narrows as it extends in the −Z direction. In other words, the width (x-dimension) of the bottom surface 91 of the third electrode 22 is smaller than the width (x-dimension) of the top surface 92 of the third electrode 22. Similar to the semiconductor device 700, the second semiconductor region 32 is configured to surround the corner portion 80 of the third electrode 22. As shown in FIG. 10, at least a part of the third electrode 22 is in contact with the second semiconductor region 32 in the X direction. The third electrode 22 is also in contact with both the first semiconductor region 31 and the second semiconductor region 32 in the Z direction. Additionally, the wall surface 90 of the third electrode 22 may be in contact with the first semiconductor region 31 in the X direction.

In such a semiconductor device 800, a first channel region is formed between the third electrode 22 and the first insulation region 51. Additionally, by narrowing the width of the lower portion of the third electrode 22 in the X direction, an area for the second semiconductor region 32 can be secured. As a result, cell pitch shrinkage becomes easier, enabling a reduction in on-resistance. Furthermore, a depletion layer formed at the interface between the first semiconductor region 31 and the second semiconductor region 32 on part of the bottom surface 91 of the third electrode 22 also helps to reduce leakage current. In other examples, in the semiconductor device 800, the bottom surface 91 of the third electrode 22 may be structured so that it does not contact the second semiconductor region 32 from the Z direction, or alternatively, the bottom surface 91 of the electrode 22 may be entirely covered by the second semiconductor region 32.

The semiconductor devices 100 through 800 can each provide a reduction in channel resistance by omitting the P-base layer from the channel region, which consequently enables a lower on-resistance. Furthermore, the second semiconductor region 32, when positioned adjacent to the third electrode 22, can effectively assist in blocking the channel current.

Semiconductor device 800 features a structure that readily enables cell pitch shrinkage, achieved by optimizing the shape of the third electrode 22 and the placement of the second semiconductor region 32. As a result, a reduction in on-resistance can be provided by use of a smaller cell pitch.

In semiconductor devices 100, 200, 300, 600, 700, and 800, a Schottky junction is formed between the third electrode 22 and the first semiconductor region 31 by not completely covering the third electrode 22 with the second semiconductor region 32. The incorporation of this Schottky junction can improve recovery speed.

In semiconductor devices 700 and 800, when the wall surface 90 of the third electrode 22 is in contact with the first semiconductor region 31 in the X direction, the bottom portion 91 of the third electrode 22 may be completely covered by the second semiconductor region 32 in some examples.

Each of the semiconductor devices according to the first embodiment and the first to seventh modification examples is designed such that the MOSFET is brought into the off-state based on the width of a depletion layer determined by the concentration of the second conductivity type.

Here, the width of a depletion layer in a general unbiased pn junction is represented by the equation (1):

$$W = \sqrt{\frac{2 {ε}_{0} {ε}_{γ}}{q} \cdot \frac{{N}_{a} + {N}_{d}}{{N}_{a} {N}_{d}} \cdot {V}_{bi}} \qquad ( 1 )$$

In equation (1), W is the width of the depletion layer, ε₀ is a permittivity of vacuum (for example, 8.85×10⁻¹⁴ F/cm), Ey is a relative permittivity of the semiconductor (for example, 11.9), q is the elementary electric charge (for example, 1.60×10⁻¹⁹ C/V), Vbi is a bulk-to-bulk potential (built-in potential) of an unbiased junction, Na is the impurity concentration of the p type, and Nd is the impurity concentration of the n type. In this context, Vbi refers to the condition where the reverse bias is zero.

When the distance in the X direction of the first channel region r1 formed between the second semiconductor region 32 and the first insulation region 51 is defined as a length L, the length L can be determined depending on the dimension of the depletion layer. The length L can be calculated in accordance with the equation (1) based on the impurity concentration of the first semiconductor region 31 and the impurity concentration of the second semiconductor region 32.

Here, for example, in order to obtain the off-state during non-energization by a Schottky barrier formed between the third electrode 22 and the first semiconductor region 31 without providing the sidewall 90 of the second semiconductor region 32 on a sidewall of the third electrode 22, it is necessary to set the length L to about 0.05 μm or less. This makes it difficult to manufacture the device because microfabrication techniques are needed. On the other hand, in the semiconductor device 100, when the concentration of n-type impurities is between 1×10¹⁵ atoms/cm³ and 1×10¹⁷ atoms/cm³ and the concentration of p-type impurities is between 1×10¹⁷ atoms/cm³ and 1×10¹⁹ atoms/cm³, the length L required to obtain the off-state during non-energization can be calculated to be about 0.1 μm to 1 μm from the equation (1). That is, from the viewpoint of processability, the present embodiment is easier to manufacture than a semiconductor device with a Schottky barrier without the second semiconductor region 32 being provided on the sidewall 90 of the third electrode 22. According to the equation (1), when the concentration of n-type impurities is 1×10¹⁵ atoms/cm³ and the concentration of p-type impurities is between 1×10¹⁷ atoms/cm³ and 1×10¹⁹ atoms/cm³, the depletion layer is about 0.9 μm to 1 μm. When the concentration of n-type impurities is 1×10¹⁶ atoms/cm³ and the concentration of p-type impurities is between 1×10¹⁷ atoms/cm³ and 1×10¹⁹ atoms/cm³, the depletion layer is about 0.3 μm. When the concentration of n-type impurities is 1×10¹⁷ atoms/cm³ and the concentration of p-type impurities is between 1×10¹⁷ atoms/cm³ and 1×10¹⁹ atoms/cm³, the depletion layer is about 0.07 μm to 0.1 μm. By controlling the width of the depletion layer according to these values, it is possible to decrease processing steps, improve the trade-off relationship with other components, and reduce the on-resistance.

### First Manufacturing Process

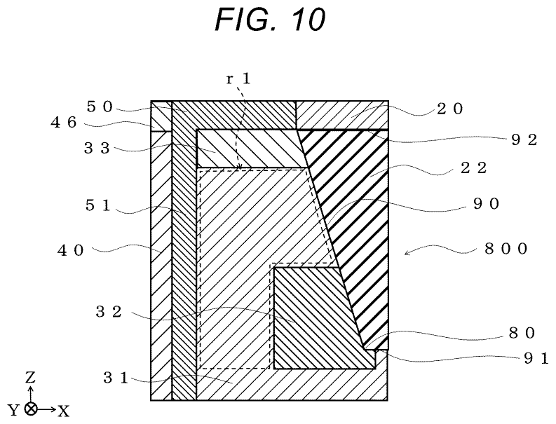

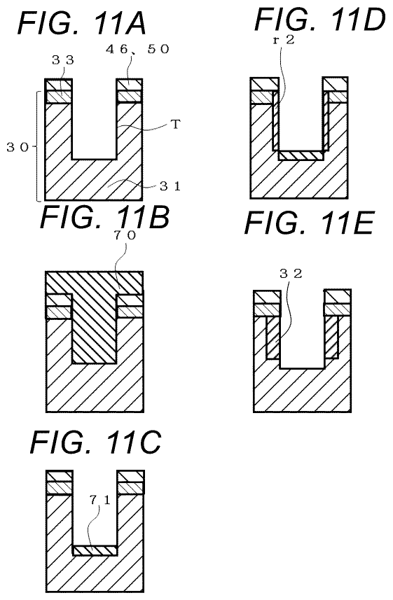

FIGS. 11A to 11E are schematic cross-sectional views of a first manufacturing process showing aspects of the manufacturing process of the third electrode 22.

As illustrated in FIG. 11A, for example, the trench T is first formed in the semiconductor portion 30. For manufacturing of the semiconductor device 800 according to the seventh modification example, by adjusting the taper angle using a Bosch-type RIE process, it is also possible to form a trench T with a narrowing width (X direction dimension) as the trench T extends downward in the Z direction. After forming of trench T, a mask material 70 is formed to fill the trench T as illustrated in FIG. 11B. The mask material 70 may be formed by a chemical vapor deposition method (CVD). Then, as illustrated in FIG. 11C, the upper surface of the mask material 70 is etched back in the thickness (Z direction dimension) by reactive ion etching (RIE) or the like, whereby an mask material 71 is left at the bottom portion of the trench T. In some examples, the mask material 71 can also be formed by filling the trench T with photoresist for a lithography process and then adjusting an exposure amount to leave the photoresist only at the bottom portion of the trench after development process or the like. Alternatively, when the photoresist in the trench T is of a positive type, the mask material 71 may be formed by developing the photoresist without exposure and performing an ashing process using oxygen plasma. Then, as illustrated in FIG. 11D, impurities of the second conductivity type are injected from the upper surface of the first semiconductor region 31 by adjusting an injection angle for ion injection. As a result, a first diffusion region r2 with the impurities of the second conductivity type is provided. The first diffusion region r2 is formed in portions of the first semiconductor region 31 and the third semiconductor region 33 exposed at the inner walls of the trench T.

After the formation of the first diffusion region r2, the mask material 71 is peeled off or otherwise removed and an annealing process is performed at a high temperature of at least 700° C. to activate the impurities in the first diffusion region r2. The second diffusion region can be grown in the annealing process in which the second semiconductor region 32 is formed. In some examples, mask material 71 may be peeled off or otherwise removed after the annealing process instead of before. It should be noted that the first diffusion region r2 does not noticeably diffuse or extend into the third semiconductor region 33 having a high impurity concentration when the second semiconductor region 32 is formed.

In the removing of the mask material 71, for example, chemical peeling may be used, but a different method may be used.

As a result, the second semiconductor region 32 to be in contact with the third electrode 22 of the semiconductor device 100 according to the first embodiment can be formed.

A trench contact as the third electrode 22 can be formed by embedding a Schottky metal in the trench T by a CVD method, a physical vapor deposition (PVD) method, or the like.

In addition, the length in the Z direction of the first diffusion region r2 formed on the exposed inner walls of the trench T in FIG. 9D can be shortened by increasing the thickness of the mask material 71 in FIG. 9C. As a result, the second semiconductor region 32 of the semiconductor device 200 according to the first modification example can be formed.

In the annealing process of the first diffusion region r2 in FIG. 11D, the first diffusion region r2 may have a concentration gradient reaching the first insulation region 51. In that case, the second semiconductor region 32 of the semiconductor device 600 according to the fifth modification example can be formed. For example, the concentration gradient can also be formed using diffusion by annealing.

By these methods, it is possible to form, in the semiconductor device 600, the second semiconductor region 32 with a concentration gradient in which the concentration of the second conductivity type decreases from the third electrode 22 toward the first insulation region 51.

### Second Manufacturing Process

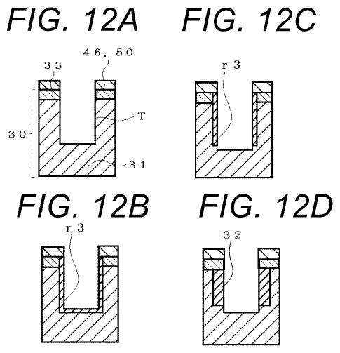

FIGS. 12A to 12D are schematic cross-sectional views of a second manufacturing process showing aspects of the manufacturing process of the third electrode 22. This is a different example of the manufacturing process of the semiconductor device 100 according to the first embodiment.

The trench T is formed as illustrated in FIG. 12A. Then, as illustrated in FIG. 12B, impurities of the second conductivity type is injected so as to cover all the exposed inner walls of the trench T. As a result, a second diffusion region r3 covering all the inner walls of the trench T is formed. The second diffusion region r3 is an impurity layer of the second conductivity type. Then, the bottom wall and part of the sidewalls adjacent to the bottom wall of the second diffusion region r3 are removed by RIE. Then, the second diffusion region r3 is grown by an annealing process, whereby the second semiconductor region 32 is formed.

Both the example of the first manufacturing process and the example of the second manufacturing process can be used to control the thickness in the X direction of the second semiconductor region 32 to be formed, in accordance with conditions of a temperature and/or a time of the annealing process.

It should be noted that the method used for removing part of the second diffusion region r3 is not limited to RIE, and a different method may be used.

In FIG. 12C and FIG. 12D, the second semiconductor region 32 of the semiconductor device 300 according to the second modification example can be formed by removing only the part of the second diffusion region r3 that is in contact with the bottom wall of the trench T by RIE and adjusting an annealing time. It should be noted that the second diffusion region r3 does not noticeably diffuse or extend into the third semiconductor region 33 having a high impurity concentration.

### Third Manufacturing Process

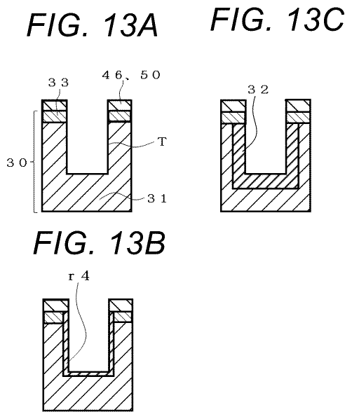

FIG. 13A to FIG. 13C are schematic cross-sectional views of a third manufacturing process showing aspects of the manufacturing process of the third electrode 22. The third manufacturing process shows an example of the semiconductor device 400 according to the third modification example.

As illustrated in FIG. 13A, the trench T is formed as described above. Then, as illustrated in FIG. 13B, impurities of the second conductivity type are injected so as to cover all the exposed inner walls of the trench T. As a result, a third diffusion region r4 covering all the inner walls of the trench T is formed. In the third manufacturing process, the third diffusion region r4 is grown by an annealing process without performing processing by RIE, whereby the second semiconductor region 32 covering all the inner walls of the trench T is formed. It should be noted that the third diffusion region r4 does not noticeably diffuse or extend into the third semiconductor region 33 having a high impurity concentration.

### Fourth Manufacturing Process

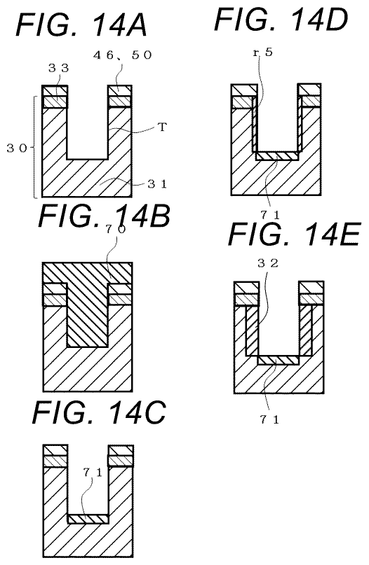

FIGS. 14A to 14E are schematic cross-sectional views of a fourth manufacturing process showing aspects of the manufacturing process of the third electrode 22. The fourth manufacturing process shows an example of the semiconductor device 500 according to the fourth modification example.

As illustrated in FIG. 14A, the trench T is formed as described above. Then, the mask material 70 is formed so as to fill the trench T, as illustrated in FIG. 14B. Subsequently, as illustrated in FIG. 14C, the upper surface of the mask material 70 is etched back by RIE or the like, whereby the mask material 71 is left at the bottom portion of the trench T. Then, as illustrated in FIG. 14D, impurities of the second conductivity type are injected from the upper surface of the first semiconductor region 31. A fourth diffusion region r5 is formed on the exposed inner walls of the trench T. The fourth diffusion region r5 is formed in portions of the first semiconductor region 31 and the third semiconductor region 33 exposed out at the inner walls of the trench T.

The mask material 71 is left at the bottom portion of the trench T without being removed, and the fourth diffusion region r5 with the impurities of the second conductivity type is grown by an annealing process. It should be noted that the fourth diffusion region r5 does not diffuse into the third semiconductor region 33 having a high impurity concentration.

While certain embodiments have been described, these embodiments have been presented by way of example only, and are not intended to limit the scope of the disclosure. For example, an Insulated Gate Bipolar Transistor (IGBT), a vertical diode, or other semiconductor chip can be used. While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first electrode;
a second electrode separated from the first electrode in a first direction;
a first semiconductor region of a first conductivity type between the first electrode and the second electrode;
a third electrode extending from the second electrode toward the first electrode in the first direction, the third electrode being on an upper side of the first semiconductor region;
a fourth electrode separated from the third electrode in a second direction orthogonal to the first direction;
a second semiconductor region of a second conductivity type between the third electrode and the fourth electrode in the second direction, the second semiconductor region contacting the third electrode;
a first insulation layer including a first insulation region contacting the fourth electrode, the first insulation region being between the third electrode and the fourth electrode in the second direction; and
a third semiconductor region of a first conductivity type between the second electrode and the second semiconductor region in the first direction, the third semiconductor region having a higher impurity concentration than the first semiconductor region.

2. The semiconductor device according to claim 1, wherein a lowermost point of the second semiconductor region is closer to the second electrode than is a lowermost point of the third electrode.

3. The semiconductor device according to claim 1, wherein a lowermost point of the second semiconductor region is closer to the first electrode than is a lowermost point of the third electrode.

4. The semiconductor device according to claim 1, wherein
the second semiconductor region is between the third electrode and the first semiconductor region in the first direction, and
the second semiconductor region surrounds an outer surface of the third electrode.

5. The semiconductor device according to claim 1, further comprising:
a second insulation layer between the third electrode and the first electrode in the first direction.

6. The semiconductor device according to claim 5, wherein the second semiconductor region contacts the second insulation layer.

7. The semiconductor device according to claim 1, wherein the second semiconductor region contacts the first insulation layer.

8. The semiconductor device according to claim 1, wherein a portion of the first semiconductor layer contacts a sidewall of the third electrode from the second direction.

9. The semiconductor device according to claim 1, wherein a portion of the first semiconductor layer is between the third electrode and the second semiconductor region in the second direction.

10. The semiconductor device according to claim 1, wherein a dimension of the first semiconductor region in the second direction between the second semiconductor region and the first insulation region is 0.1 to 1 μm.

11. The semiconductor device according to claim 1, further comprising:
a fifth electrode between the fourth electrode and the first electrode in the first direction, the fifth electrode being electrically insulated from the fourth electrode by a portion of the first insulating layer.

12. The semiconductor device according to claim 1, wherein
the third electrode has a top surface that faces and contacts the second electrode in the first direction and a bottom surface that faces and contacts the first semiconductor region in the first direction, and
a width of the bottom surface along the second direction is less than that of the top surface.

13. The semiconductor device according to claim 12, wherein the third electrode faces and contacts both the first semiconductor region and the second semiconductor region in the first direction.

14. The semiconductor device according to claim 1, wherein the third electrode faces and contacts both the first semiconductor region and the second semiconductor region in the first direction.

15. A semiconductor device, comprising:
a first electrode;
a second electrode separated from the first electrode in a first direction;
a first semiconductor region of a first conductivity type between the first electrode and the second electrode;
a third electrode extending from the second electrode toward the first electrode in the first direction, the third electrode being on an upper side of the first semiconductor region;
a fourth electrode separated from the third electrode in a second direction orthogonal to the first direction;
an insulation layer including a first insulation region, the first insulation region being in contact with the fourth electrode and facing the third electrode in the second direction; and
a second semiconductor region of a second conductivity type having a concentration gradient of impurities of a second conductivity type along the second direction, the second semiconductor region being between the third electrode and the first insulation region and contacting both the third electrode and the first insulation region from the second direction.

16. The semiconductor device according to claim 15, wherein the concentration gradient has a concentration decreasing from the third electrode toward the first insulation region.

17. The semiconductor device according to claim 15, wherein the concentration gradient has a Gaussian distribution.

18. The semiconductor device according to claim 15, further comprising:
a fifth electrode between the fourth electrode and the first electrode in the first direction, the fifth electrode being electrically insulated from the fourth electrode by a portion of the insulating layer.

19. A semiconductor device, comprising:
a first semiconductor region of a first conductivity type between a first electrode and a second electrode in a first direction;
a third electrode extending from the second electrode toward the first electrode in the first direction;
a gate electrode separated from the third electrode in a second direction orthogonal to the first direction;
a second semiconductor region of a second conductivity type between the third electrode and the gate electrode in the second direction, the second semiconductor region contacting at least sidewall of the third electrode; and
an insulation layer surrounding the gate electrode and being between the third electrode and the between electrode in the second direction.

20. The semiconductor device according to claim 19, further comprising:
a third semiconductor region of first conductivity type between the second electrode and the second semiconductor region in the first direction, the third semiconductor region having a higher impurity concentration than the first semiconductor region.
